(19) United States
(12) Patent Application Publication
(10) Pub. No.: US 2013/0341711 A1
(43) Pub. Date: Dec. 26, 2013

(54) SEMICONDUCTOR DEVICE

(71) Applicant: Hitachi, Ltd., Tokyo (JP)

(72) Inventors: Daisuke Matsumoto, Tokyo (JP); Toshiyuki Ohno, Hitachi (JP); Hirotaka Hamamura, Kodaira (JP)

(21) Appl. No.: 13/921,398

(22) Filed: Jun. 19, 2013

(30) Foreign Application Priority Data
Jun. 20, 2012 (JP) 2012-138317

(51) Int. Cl. H01L 29/78; H01L 29/06

(52) U.S. Cl. CPC H01L 29/7827; H01L 29/06
USPC 257/330; 257/622

(57) ABSTRACT

A technique for improving the characteristics of a semiconductor device (UMOSFET) is provided. In the UMOSFET in order to grow an epitaxial growth film on a trench side wall with an even film thickness, a channel is arranged in an optimum direction as a growth surface. For example, a trench is formed on an SiC substrate having a {0001} surface 4° off in a <11-20> direction as a main surface so that a channel surface becomes a {1-100} surface. With this configuration, an epitaxial growth with the even thickness can be conducted on the side wall from which the {1-100} surface of the trench is exposed. As a result, the unevenness of a channel resistance, and the insulation failure of a gate insulating film do not occur, and the yield is improved.

### BACKGROUND OF THE INVENTION

1. Field of the Invention

The present invention relates to a semiconductor device and a method of manufacturing the semiconductor device, and particularly to a technique which is effectively applied to an UMOSFET (metal oxide semiconductor field effect transistor).

2. Background Art

On the background of global environmental protection, a reduction in the emission of carbon dioxide which is one of greenhouse gases has been demanded. For that reason, electric power saving of a wide variety of electronic devices has been increasingly required. Among those electronic devices, a requirement in railroad, automobile, and electric power fields which consume a large amount of power is strong, and the electric power saving of semiconductor power devices for controlling their electric powers has been encouraged. In order to reduce a power loss, a reduction in an on-resistance becomes a challenge for the power devices such as transistors or diodes. Under such circumstances, attention is paid to the power device using silicon carbide (SiC). SiC is a material indicative of a variety of polytypes, and 4H—SiC that is one of polytypes has a breakdown strength which is 10 times as large as Si mainly used at present. For that reason, in a variety of semiconductor devices, a thickness of adrift layer of 4H—SiC can be reduced to 1/10 if 4H—SiC has the same breakdown specification as that of Si. According to a Poisson equation, this means that a carrier concentration can be increased to 100 times. If a mobility is kept constant without depending on the carrier concentration, a resistance of the drift layer can be reduced by about double digits to triple digits. Further, in the case of a MOSFET, there is advantageous in that a switching loss is small in the inverter application. That is, the remarkable power saving can be expected as compared with the related art Si power device. Further, since a high-temperature operation can be physically conducted, a cooling system can be reduced, and can be downsized as an overall system. However, currently, a substrate price becomes a bottleneck, and a system of 4H—SiC is relatively expensive as compared with the system of Si. In the future, it is conceivable that since a chip unit price is decreased with a larger diameter of the substrate, and the cooling system can be reduced in the costs, the SiC power device becomes comprehensively predominant.

Under the above circumstances, the MOSFET has been developed as a switching element. The MOSFET can conduct normally-off operation in principle, and is convenient, and the application of the MOSFET over a wide range is expected. Since a high pressure resistance is demanded for the MOSFET, the vertical structures are adopted. The vertical structures have two types of a planar type using a wafer plane as a channel, and a trench type forming a trench, and using a side wall of the trench as the channel. Since the trench type MOSFET (UMOSFET) can be subjected to high integration, but has a plane direction dependency, there have been proposed a method of identifying the direction (for example, refer to JP-A-2009-187966), a trench forming method (for example, refer to JP-A-2009-289987), a method of reducing an electric field to be applied to a trench bottom (for example, refer to JP-A-2009-278067 and JP-A-2009-117593). However, attention needs to be paid to a method of forming a channel surface because in the MOSFET, a top surface of 10 to 100 nm order in depth forms the channel, and the performances such as the mobility and the reliability of a gate insulating film formed immediately over the channel are sensitive to a surface state. For that reason, surface processing is implemented immediately before the gate insulating film is formed. As a method of the surface processing, there is an epitaxial growth. The epitaxial growth is a technique of allowing an SiC film to grow, which is different from a method of removing a surface layer such as sacrificial oxidation or hydrogen etching. In particular, in the case of the UMOSFET, since a damage caused by the process is larger than that of the planar type because the channel surface is formed by dry etching, it is conceivable that the applied effect of the surface processing process is large. With the application of the surface processing method, an improvement in the performance of the SiC-MOSFET can be expected.

### SUMMARY OF THE INVENTION

The present inventors have been engaged in research and development of the power devices, and have studied an improvement in the characteristics such as a reduction in the on-resistance of the above UMOSFET, and an improvement in the reliability of the gate insulating film. As means for improving the characteristics, the present inventors have studied the application of the epitaxial growth process, but there arise the following problems. A substrate used for the epitaxial growth process is mainly formed of a 4H—SiC, 4° off substrate at present. Therefore, if the trench is formed, a crystal plane is different from each other between a trench side wall and a wafer surface. For example, when a rectangular trench is formed on a generally used SiC substrate having a {0001} surface 4° off in a <11-20> direction as a main surface, there appear six surfaces in total including four side walls of the trench, a wafer main surface, and a trench bottom as illustrated in FIG. 21. The wafer main surface and the trench bottom are each, crystallographically, a {0001} surface. Attention needs to be paid to the identification of the crystal surface of the trench side wall. An A-surface and a B-surface in the figure are each a {1-100} surface, and a C-surface and a D-surface are surfaces inclined from a {11-20} surface by 4 degrees and −4 degrees, respectively, and the six surfaces are configured by three kinds of surfaces.

According to the experimental results by the present inventors, because a growth rate of the epitaxial growth strongly depends on the crystal surface, it is difficult to conduct the epitaxial growth with a uniform thickness in the above trench structure. When the epitaxial growth is to be conducted in the UMOSFET, the film thickness unevenness induces the unevenness of the channel, and the insulation failure of a gate oxide film formed immediately over the channel, resulting in a problem that the yield is degraded.

In order to allow the epitaxial growth film to grow on the trench side wall with a uniform thickness, the channel is arranged in an optimum direction as a growth surface. For example, the trench is formed so that the channel surface becomes the {1-100} surface with respect to the SiC substrate having the {0001} surface 4° off in the <11-20> direction as the main surface. With the above configuration, the epitaxial growth with a uniform thickness can be conducted on the side wall where the {1-100} surface of the trench is exposed. As a result, the unevenness of the channel resistance and the insulation failure of the gate insulating film do not occur, and the yield is improved.

According to the present invention, a process likelihood in the epitaxial growth process of the semiconductor device is improved, thereby being capable of improving the yield.

### BRIEF DESCRIPTION OF THE DRAWINGS

FIG. 1 is a plan view of a main portion of a semiconductor device according to a first embodiment;

FIG. 2 is a cross-sectional view of the main portion of the semiconductor device according to the first embodiment;

FIG. 3 is a cross-sectional view illustrating a main portion of a process of manufacturing the semiconductor device according to the first embodiment;

FIG. 4 is a cross-sectional view illustrating a main portion of a process of manufacturing the semiconductor device according to the first embodiment, which is a cross-sectional view of the main portion during the process of manufacturing the semiconductor device subsequent to FIG. 3;

FIG. 5 is a plan view illustrating the main portion of the process of manufacturing the semiconductor device according to the first embodiment;

FIG. 6 is a cross-sectional view illustrating a main portion of a process of manufacturing the semiconductor device according to the first embodiment, which is a cross-sectional view of the main portion during the process of manufacturing the semiconductor device subsequent to FIG. 4;

FIG. 7 is a plan view illustrating the main portion of the process of manufacturing the semiconductor device according to the first embodiment;

FIG. 8 is a cross-sectional view illustrating a main portion of a process of manufacturing the semiconductor device according to the first embodiment, which is a cross-sectional view of the main portion during the process of manufacturing the semiconductor device subsequent to FIG. 6;

FIG. 9 is a plan view illustrating the main portion of the process of manufacturing the semiconductor device according to the first embodiment;

FIG. 10 is a cross-sectional view illustrating a main portion of a process of manufacturing the semiconductor device according to the first embodiment, which is a cross-sectional view of the main portion during the process of manufacturing the semiconductor device subsequent to FIG. 8;

FIG. 11 is a plan view illustrating the main portion of the process of manufacturing the semiconductor device according to the first embodiment;

FIG. 12 is a cross-sectional view illustrating a main portion of a process of manufacturing the semiconductor device according to the first embodiment, which is a cross-sectional view of the main portion during the process of manufacturing the semiconductor device subsequent to FIG. 10;

FIG. 13 is a cross-sectional view illustrating a main portion of a process of manufacturing the semiconductor device according to the first embodiment, which is a cross-sectional view of the main portion during the process of manufacturing the semiconductor device subsequent to FIG. 12;

FIG. 14 is a cross-sectional view illustrating a main portion of a process of manufacturing the semiconductor device according to the first embodiment, which is a cross-sectional view of the main portion during the process of manufacturing the semiconductor device subsequent to FIG. 13;

FIG. 15 is a cross-sectional view illustrating a main portion of a process of manufacturing the semiconductor device according to the first embodiment, which is a cross-sectional view of the main portion during the process of manufacturing the semiconductor device subsequent to FIG. 14;

FIG. 16 is a plan view illustrating the main portion of the process of manufacturing the semiconductor device according to the first embodiment;

FIG. 17 is a cross-sectional view illustrating a main portion of a process of manufacturing the semiconductor device according to the first embodiment, which is a cross-sectional view of the main portion during the process of manufacturing the semiconductor device subsequent to FIG. 15;

FIG. 18 is a cross-sectional view illustrating a main portion of a process of manufacturing the semiconductor device according to the first embodiment, which is a cross-sectional view of the main portion during the process of manufacturing the semiconductor device subsequent to FIG. 17;

FIG. 19 is a plan view of a main portion of a semiconductor device according to a second embodiment;

FIG. 20 is a cross-sectional view of a main portion of a semiconductor device according to a third embodiment; and

FIG. 21 is a diagram illustrating a plane direction on a 4H—SiC, 4° off substrate.

### DETAILED DESCRIPTION

Hereinafter, embodiments according to the present invention will be described with reference to the drawings.

### First Embodiment

### [Description of Structure]

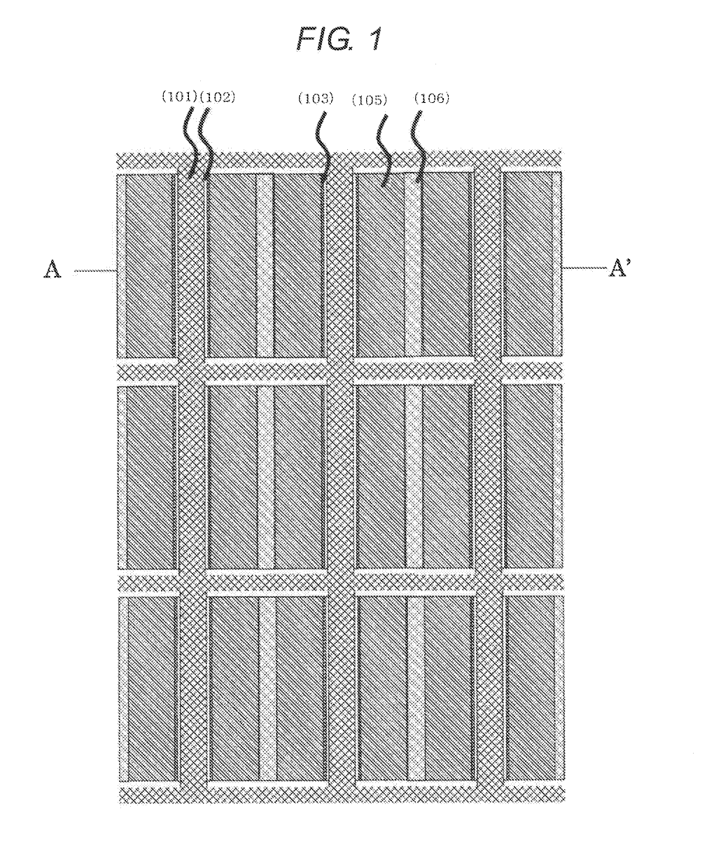

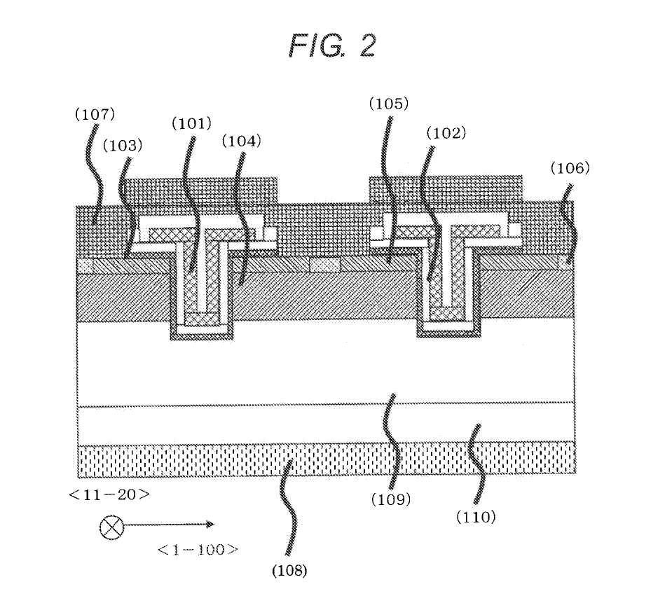

A configuration of a semiconductor device (UMOSFET) according to this embodiment will be described with reference to FIGS. 1 and 2. FIG. 1 is a cross-sectional view of a main portion of the semiconductor device according to this embodiment. FIG. 2 is a cross-sectional view taken along a line A-A′ in FIG. 1.

As illustrated in FIG. 1, according to this embodiment, cell regions, which are rectangular regions each surrounded by a dotted line in FIG. 1, are line-symmetrically repetitively arranged in an X-direction (a lateral direction or a horizontal direction in the figure) and in a Y-direction (a longitudinal direction or a vertical direction in the figure) A plurality of the cell regions are arranged in the X-direction and the Y-direction to configure one semiconductor device (UMOSFET). The plurality of cell regions configuring the semiconductor device (UMOSFET) may be called “cell array region (array region, or array). Also, although FIG. 1 illustrates only nine cell regions of 3×3, the semiconductor device (UMOSFET) may be configured by using nine or more cell regions, or the semiconductor device (UMOSFET) may be configured by nine or less cell regions.

The semiconductor device described below is formed on a substrate in which an SiC epitaxially grown film (109) called “drift layer” is deposited on an SiC substrate (110). A gate electrode (101) illustrated in FIG. 2 is arranged in the center of each cell region. The gate electrode (101) illustrated in FIG. 2 is made of a high melting point metal material such as polycrystal silicon added with impurities or tungsten. The choice of the material is a design particular such as a manufacturing process and a work function of the respective materials. A gate insulating film (102) illustrated in the figure may be made of a thermally oxidized film such as SiO₂, a deposited film, or a high-permittivity dielectric material such as alumina, and may be formed of a lamination of those films, or a single layer. In the figure, the gate insulating film (102) is illustrated as one lump. An SiC epitaxial growth film (103), a p body region (104), an n+ region (105), and a p+ region (106) are formed as illustrated in the figure. The impurity concentration of those regions is adjusted according to the design of a source resistance, a silicide resistance of a silicide layer formed on the source resistance, a potential maintaining performance and a threshold voltage of the p body region, or an adhesion performance of the p body region and a source electrode (107) formed on the p body region. The source electrode (107) is formed as illustrated in the figure, and made of metal material such as aluminum, and desirably low in resistance. It is desirable that the adhesion of the source electrode (107) and the silicide layer formed below the source electrode (107) is also high. Although not illustrated in the figure, a silicide layer in which a metal material such as Ni chemically reacts with SiC is disposed in an interface between the source electrode and the wafer, and an electric contact of the source electrode (107) and the wafer is formed as an ohmic contact. Similarly, a silicide layer for forming the electric contact as the ohmic contact is formed on a lower portion of the wafer, and a metal material such as Ni or Ti is connected onto the silicide layer to form a drain electrode (108).

The above semiconductor device is generally called “trench MOSFET” or “UMOSFET”, and a voltage to be applied to the gate electrode is controlled to control a channel resistance configuring a resistance value between the source electrode (107) and the drain electrode (108). In an extreme case, the channel resistance is remarkably increased to decrease a current between the source electrode (107) and the drain electrode (108) (off-operation). Conversely, the channel resistance is extremely decreased to increase the current between the source electrode (107) and the drain electrode (108) (on-operation). That is, a switch of a current between terminals of the source electrode (107) and the drain electrode (108) turns on/off, and is generally called “switching element” because of that characteristic. The UMOSFET is one configuration of the switching element. A DMOSFET (double diffused FET) is present as another configuration, and a description thereof will be omitted in this example.

The principle of the on-operation will be described. A positive voltage is applied to the drain electrode (108) while the source electrode is 0V. Therefore, a current flows from the drain electrode (108) toward the source electrode (107). A flow of electrons which are carriers is opposite to that of the current. When a positive voltage is applied to the gate electrode, a free electron layer called “channel” is formed on the epitaxial growth film (103) grown on the trench side wall. For that reason, a current that flown through the drain electrode (108), the substrate (110), and the drift layer (109) passes into the source electrode (107) through the n+ region (105) from the channel region. This is the principle of the on-operation. On the other hand, in the general MOSFET, no channel is formed when the gate electrode is 0V. Also, a current is cut off by a pn junction formed between the drift layer (109) and the p body region (104). This is the operation principle of the off operation. In general, a voltage value to be applied to the gate electrode which becomes a threshold value for opening or closing the channel is called “threshold voltage”. There are a variety of accurate definitions of the threshold voltage, but in this example, the threshold voltage is defined as the voltage for opening or closing the channel.

The basic operation is described above. In the present invention, the epitaxial growth layer (103) arranged between the p body region (104) and the gate insulating film (102) is arranged with a layer for recovering a damage of crystal due to dry etching for forming the trench, or ion implantation for forming the p body region (104). With this configuration, the channel mobility and the reliability are expected to be improved. That layer is arranged provided that the epitaxial thickness within the trench is kept uniform. In the related art epitaxial growth technique, it is difficult to epitaxially grow the layer with a uniform thickness on the trench inner wall, and a technique for controlling the growth is important. If the evenness is not kept, a degradation of the yield due to the unevenness of the channel resistance is problematic. Further, there arises such a problem that the gate oxide film becomes uneven in a post-process, resulting in a problem that the insulating film reliability is degraded. Therefore, in order to avoid those problems, it is important that the epitaxial film has an even thickness. The most importance for the uniform film growth is an epitaxial growth rate. It is needless to say that the growth rate depends on a growth condition such as a material gas quantity, and in order to grow the film with the even thickness, it is most important what a crystal plane on the trench side wall is. As described above, because the crystal plane different in principle is exposed in the UMOSFET, it is unavoidable that the growth rate is different in the respective planes. Under the circumstances, all of the planes used as the channel are configured by {1-100} surfaces that can be made identical with each other, and a termination portion of the cell is configured by a {11-20} surface, or a surface conforming to the {11-20} surface. With this configuration, the epitaxial growth with the even thickness can be conducted on the channel.

A second problem is that because the {11-20} surface is exposed in the termination portion of the cell, the thickness becomes uneven in that portion, and the above-mentioned problem becomes manifested. Under the circumstances, in order to avoid the problem, the gate electrode is arranged as illustrated in the figure, and the gate electrode is prevented from being formed in the termination portion. With this configuration, the semiconductor device with an excellent characteristic can be manufactured.

### [Description of Manufacturing Method]

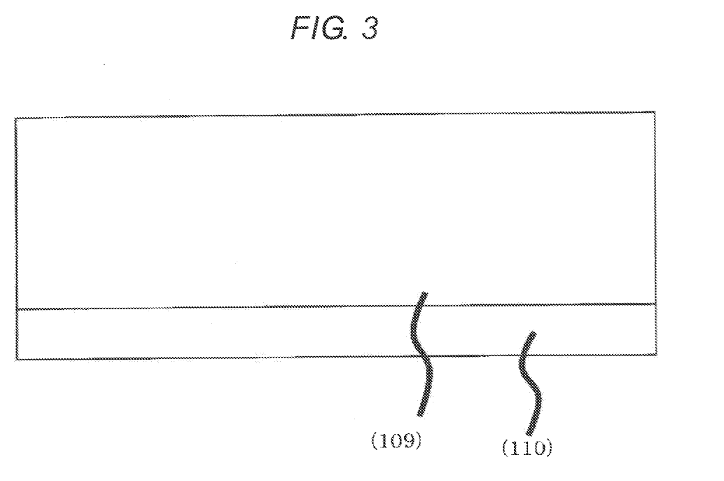

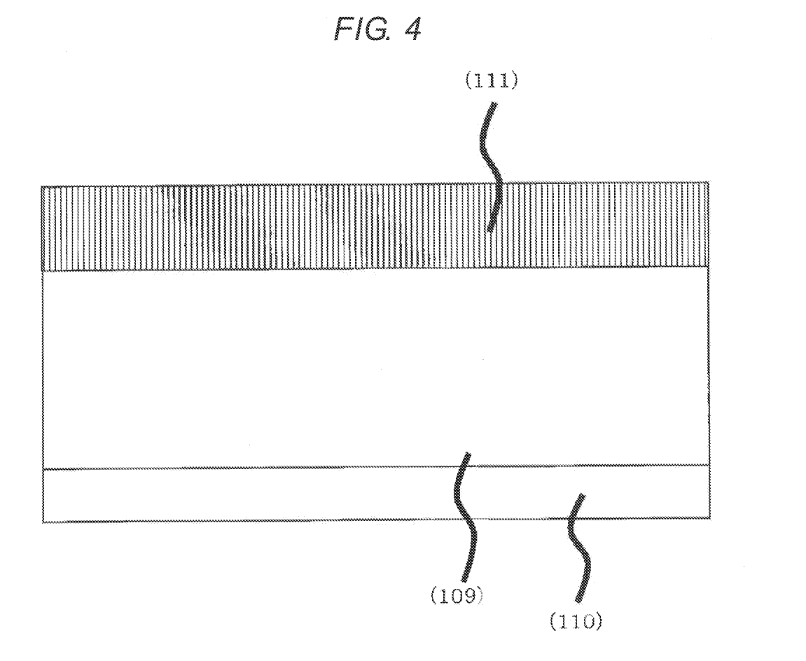

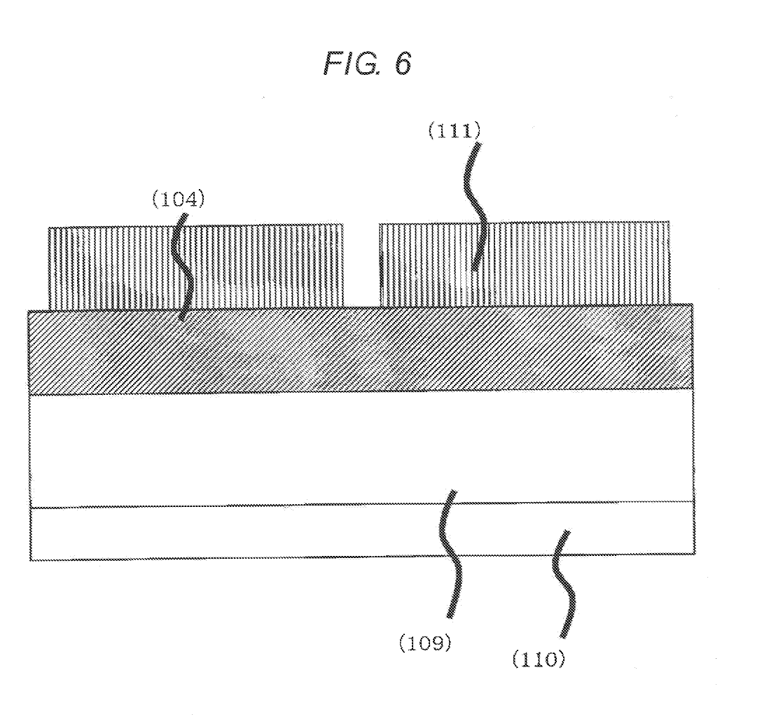

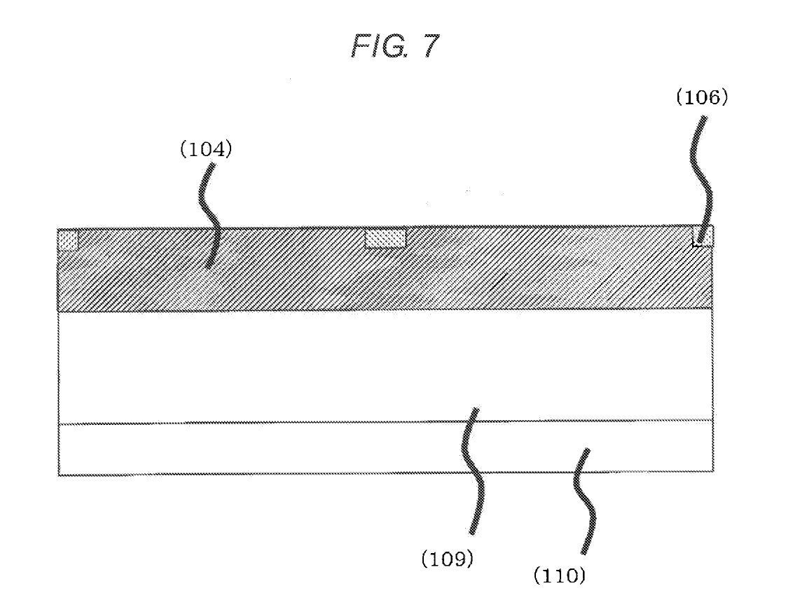

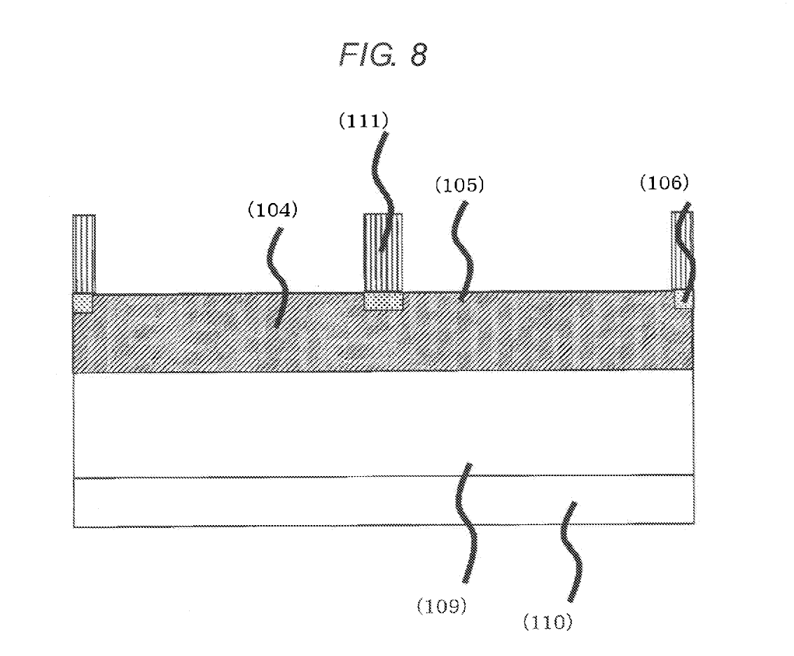

Subsequently, a method of manufacturing the semiconductor device according to this embodiment will be described with reference to FIGS. 3 to 18, and the configuration of the semiconductor device will be more clarified. FIG. 3 to FIG. 18 are cross-sectional views or plan views illustrating the main portions of the process of manufacturing the semiconductor device according to this embodiment.

As illustrated in FIG. 3, for example, the SiC substrate (110) is prepared as the substrate. The SiC substrate (110) is, for example, an n⁺ type 4H—SiC substrate (SiC substrate of a hexagonal crystal). For the formation of the drift layer which will be described later, the substrate needs to be formed with an inclination from a {0001} surface by a given angle, which is called “off angle”. The off angle is, for example, 8°, 4°, 2°, or 0.5°. The impurity concentration of the substrate falls within, for example, a range of 1×10¹⁸ to 1×10²¹ cm⁻². As the n-type impurity, the substrate contains, for example, nitrogen (N). Also, one surface of the 4H—SiC substrate (110) has an Si surface terminated with Si, and the other surface of the 4H—SiC substrate (110) has a C surface terminated with C (carbon) because of the crystalline. Any surface may be used as a front surface. In other words, the semiconductor device which will be described later may be formed on any surface.

A semiconductor region made of SiC is grown on the front surface of the SiC substrate (110) through the epitaxial growth method to form the n⁻ drift layer (109). For example, 4H—SiC is epitaxially grown on the substrate (110) with a thickness of about 2 μm to 50 μm, using a source gas of, for example, SiH₄, or Si₂H₆ as an Si source, or CH₄, C₂H₆, and C₃H₈ as a C source. In this situation, nitrogen (N₂) is contained in the source gas, to thereby introduce the n type impurities into the formed epitaxial film. The thickness and the impurity concentration of the drift layer (109) depend on a withstand design of the device and a designed value such as the resistance value. The n⁻ drift layer (109) and the p body region (104) which will be described later configure the pn junction. Hence, the impurity concentrations of those semiconductor regions (104, 109) become factors for determining a width of a depletion layer of the pn junction. The impurity concentration of the n⁻ drift layer (109) falls within a range of, for example, 1×10¹⁴ to 1×10¹⁸ cm⁻³. A laminated body of the SiC substrate (110) and the n⁻ drift layer (109) may be regarded as the substrate.

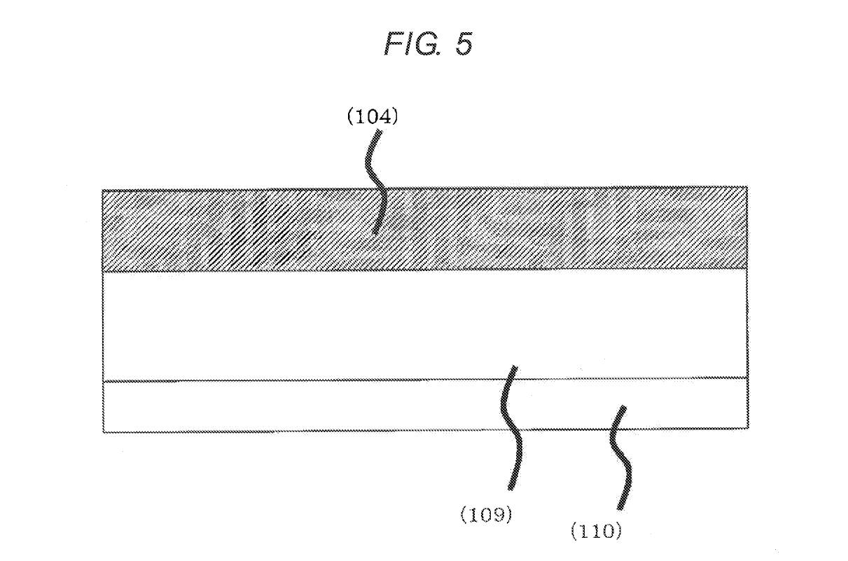

Subsequently, the p body region (104) is partially formed on the front surface of the n⁻ drift layer (109). More specifically, a photoresist film (111) is coated on the n⁻ drift layer (109), and a pattern is exposed and transferred. Thereafter, development processing is conducted (photolithography). After the pattern has been drawn by using an electron beam, the development processing may be conducted. As a result, the region in which the p body region (104) is not formed is covered with the photoresist film (111). With the developed photoresist film (111) as a mask, p-type impurities are implanted into the n⁻ drift layer (109), to thereby form the p body region (104). For example, an implantation depth of the impurities is, for example, about 1 μm. Also, the impurity concentration falls within a range of, for example, 1×10¹⁶ to 1×10¹⁹ cm⁻³. Also, for example, Al (aluminum) or B (boron) is used as the p type impurities. Since a resistance property of the photoresist film (111) may be short depending on an implantation energy or the amount of implantation of the impurities, for example, SiO₂ may be used as a high resistant mask called “hard mask”. In this situation, a photoresist mask is coated on the high resistant mask, and a pattern is formed through the same process as that described above. Thereafter, SiO₂ is etched through a technique such as a dry etching or a wet etching with the photoresist mask as the mask. With this processing, an SiO₂ mask onto which a photoresist mask pattern has been transferred is completed, and the impurities are implanted from above this mask. Thereafter, the photoresist film (111) is removed by ashing, to thereby form the p body region (104) as illustrated in FIG. 5. When the high resistant mask is used, the photoresist film (ill) is removed by processing corresponding to the high resistant mask. For example, when SiO₂ is used, the photoresist film (111) is removed by wet etching of hydrofluoric acid or hydrofluoric acid diluted with water after ashing.

Subsequently, the p⁺ region (106) is formed. Specifically, the photoresist film (111) is coated on the substrate, the pattern is exposed and transferred, and thereafter the development processing is conducted. As a result, the photoresist film (111) remains. With the developed photoresist film (111) as a mask, the p-type impurities are implanted into the n⁻ drift layer (109), to thereby form the p+ region (106). For example, an implantation depth of the impurities is, for example, about 0.1 μm to 0.5 μm. The depth is determined by adjusting the implantation energy of the impurities. The impurity concentration is set to, for example, about 1×10¹⁸ to 1×10²¹ cm⁻³. Also, for example, Al (aluminum) or B (boron) is used as the p type impurities. Since a resistance property of the photoresist film (111) may be short depending on the implantation energy or the amount of implantation of the impurities, for example, SiO₂ may be used as the “hard mask”. In this situation, a photoresist mask is coated on the high resistant mask, and a pattern is formed through the same process as that described above. Thereafter, SiO₂ is etched through a technique such as a dry etching or a wet etching with the photoresist mask as the mask. With this processing, an SiO₂ mask onto which a photoresist mask pattern has been transferred is completed, and the impurities are implanted from above this mask. Thereafter, the photoresist film (111) is removed by ashing, to thereby form the p⁺ body region (106). Also, when SiO₂ is used as the hard mask, the photoresist film (111) is removed by wet etching of hydrofluoric acid after ashing.

Subsequently, the n⁺ region (105) is formed. Specifically, the photoresist film (111) is coated on the substrate, the pattern is exposed and transferred, and thereafter the development processing is conducted. As a result, the photoresist film (111) having an n+ region (105) formation region opened remains. With the developed photoresist film (111) as a mask, the n-type impurities are implanted into the p body region (104), to thereby form the n⁺ source region (105). For example, an implantation depth of the impurities is, for example, about 0.1 μm to 0.5 μm. With this processing, the n⁺ region (105) is formed on the front surface of the p body region (104). The impurity concentration falls within a range of, for example, 1×10¹⁸ to 1×10²¹ cm⁻³. Also, for example, N (nitrogen) or P (phosphorus) is used as the n type impurities. Since a resistance property of the photoresist film (111) may be short depending on the implantation energy or the amount of implantation of the impurities, for example, SiO₂ may be used as the hard mask. In this situation, a photoresist mask is coated on the hard mask, and a pattern is formed through the same process as that described above. Thereafter, SiO₂ is etched through a technique such as a dry etching or a wet etching with the photoresist mask as the mask. With this processing, an SiO₂ mask onto which a photoresist mask pattern has been transferred is completed, and the impurities are implanted from above this mask.

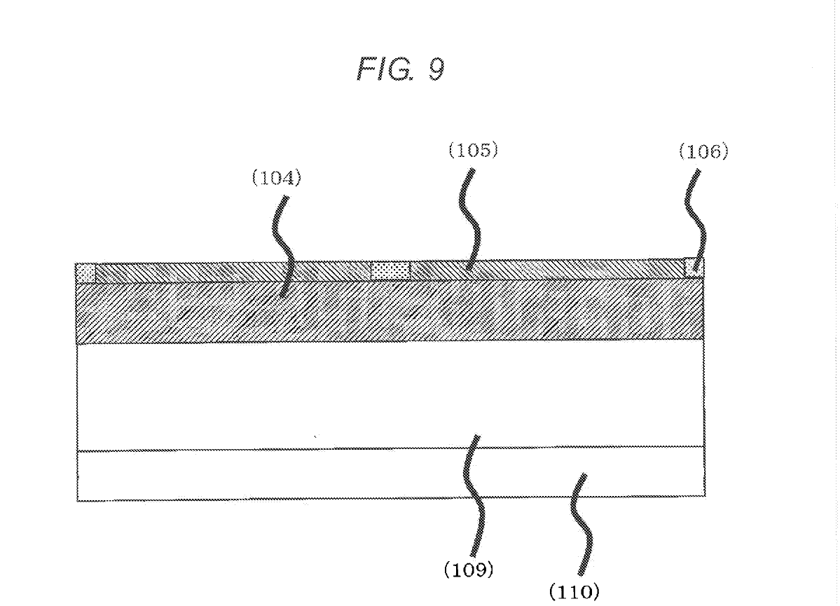

Thereafter, the photoresist film (111) is removed by ashing, to thereby form the n+ source region (105). FIG. 9 illustrates the formation region of the n+ source region (105) by dot hatching. For example, when SiO₂ is used as the hard mask, the photoresist film (111) is removed by wet etching of hydrofluoric acid or hydrofluoric acid diluted with water after ashing.

The order of the wide variety of ion introduction (implantation) processing is not limited to the above processing. For example, the respective semiconductor regions (impurity regions 104, 105, and 106) can be formed at position indicated in FIGS. 1 and 2 by adjusting the implantation conditions (the type and concentration of the impurity ions, the implantation energy, etc.). Hence, for example, after the p⁺ region (106) has been formed, the p body region (104) may be formed, and the respective semiconductor regions may be formed in any order.

Then, for the purpose of recovering the crystalline disturbed through the above ion introduction (implantation) processing, and activating the introduced impurities, anneal processing (heat treatment) is conducted in an Ar or Ar/SiH₄ atmosphere of, for example, about 1600 to 1800° C.

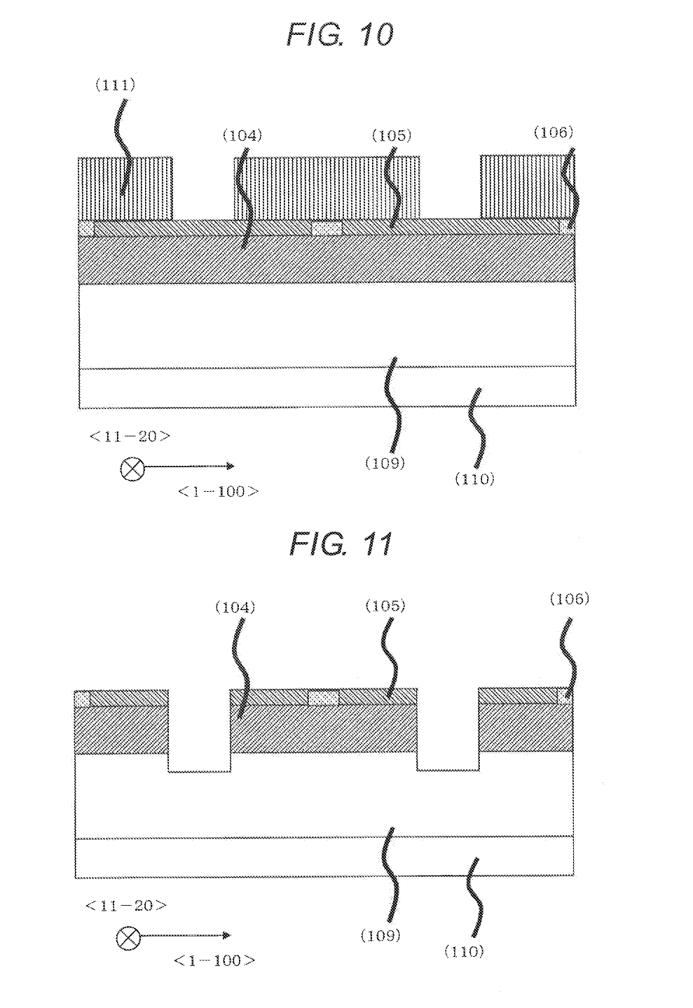

Then, as illustrated in FIG. 10, the trench is formed in the gate formation portion. Specifically, the photoresist film (111) is coated on the above wafer, the pattern is exposed and transferred, and thereafter the development processing is conducted. As a result, the photoresist film (111) having the trench formation region opened remains. In this situation, a longitudinal direction of the trench is set to a <11-20> direction, and the photoresist film (111) is patterned to expose the {11-20} surface in a lateral direction. With the developed photoresist film (111) as a mask, the trench is formed by dry etching. The depth of the trench is deeper than that of the p body region. Since a resistance property of the photoresist film (111) may be short depending on the depth of the trench, for example, SiO₂ may be used as the hard mask. In this situation, a photoresist mask is coated on the hard mask, and a pattern is formed through the same process as that described above. Thereafter, SiO₂ is etched through a technique such as a dry etching or a wet etching with the photoresist mask as the mask. With this processing, an SiO₂ mask onto which a photoresist mask pattern has been transferred is completed. SiC is dry-etched from above this mask to form the trench. Thereafter, as illustrated in FIG. 11, the photoresist film (111) is removed by ashing, to thereby form the trench. For example, when SiO₂ is used as the hard mask, the photoresist film (111) is removed by wet etching of hydrofluoric acid after ashing.

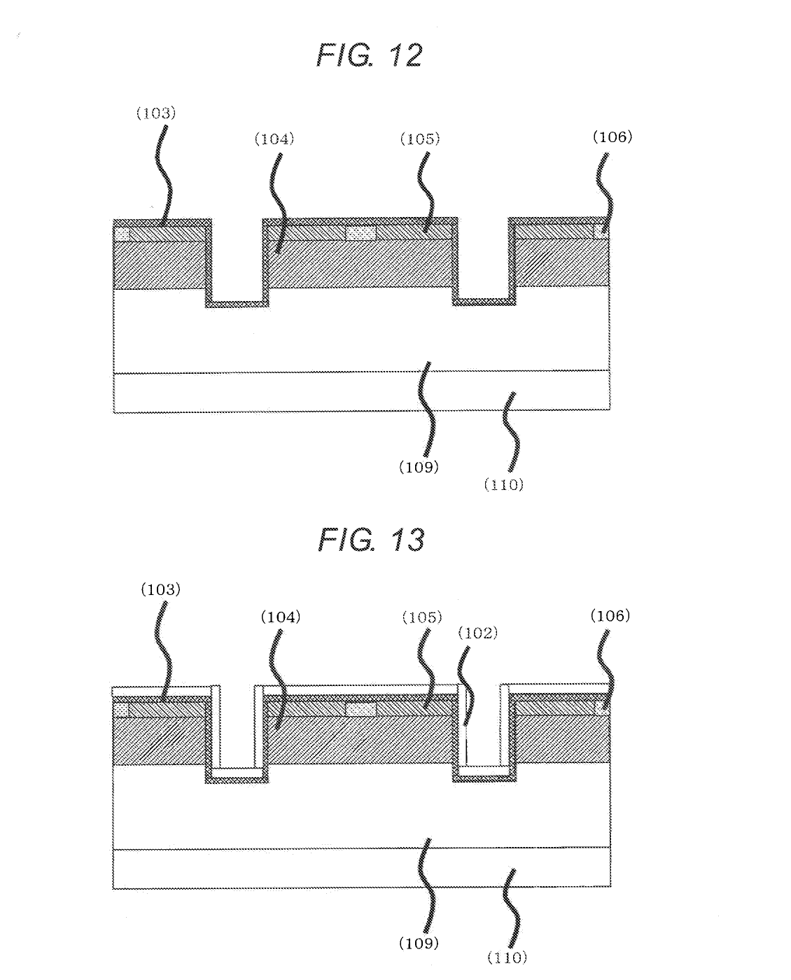

Then, as illustrated in FIG. 12, the epitaxial film (103) is formed. For example, 4H—SiC is epitaxially grown on the substrate (110) with a thickness of about 0.01 μm to 0.3 μm, using a source gas of, for example, SiH₄ or Si₂H₆ as an Si source, or CH₄, C₂H₆, and C₃H₈ as a C source. In this situation, nitrogen (N₂) is contained in the source gas, to thereby introduce the n type impurities into the formed epitaxial film. The thickness and the impurity concentration of the epitaxial film (103) depend on designed values of the threshold voltage or the resistance value. The impurity concentration of the epitaxial film falls within a range of, for example, 1×10¹⁴ to 1×10¹⁸ cm⁻³.

Then, as illustrated in FIG. 13, a gate insulating film is formed. Specifically, a thermally oxidized film made of SiO₂, a deposited film formed through a variety of CVD (chemical vapor deposition) techniques, or a high-permittivity dielectric material such as alumina may be used for the gate insulating film, and those insulating materials may be stacked on each other, or used as a single layer.

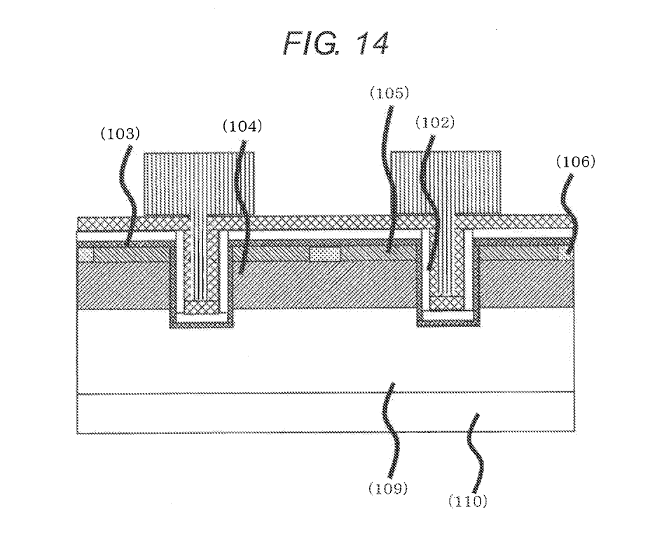

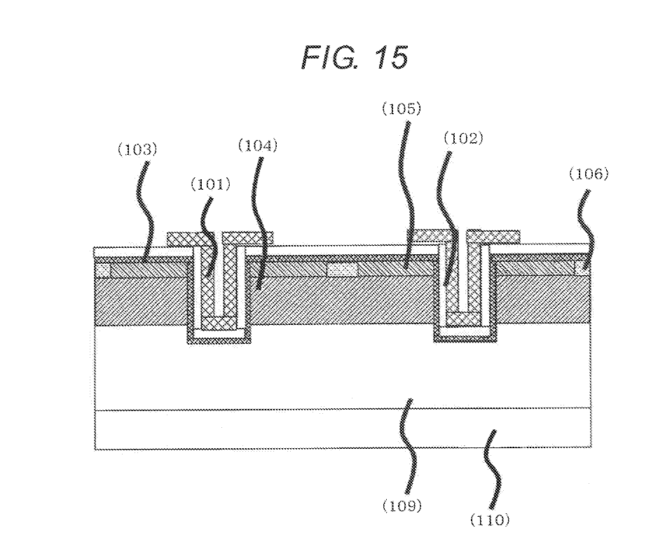

Then, as illustrated in FIG. 14, a material forming a gate electrode is formed on the front surface of the substrate through a variety of CVD (chemical vapor deposition) techniques, or a sputtering technique. As the gate electrode material, there is used a high melting point metal material such as polycrystal silicon added with impurities or tungsten. The choice of the material is a design particular depending on a manufacturing process and a work function of the respective materials. The photoresist film (111) is coated on the gate electrode, a pattern is exposed and transferred, and thereafter the development processing is conducted. With this processing, the photoresist film (111) opened except for the gate electrode portion remains. With the developed photoresist film (111) as a mask, the gate electrode is formed by dry etching or wet etching. Thereafter, as illustrated in FIG. 15, the photoresist film (111) is removed by ashing to form the gate electrode (101).

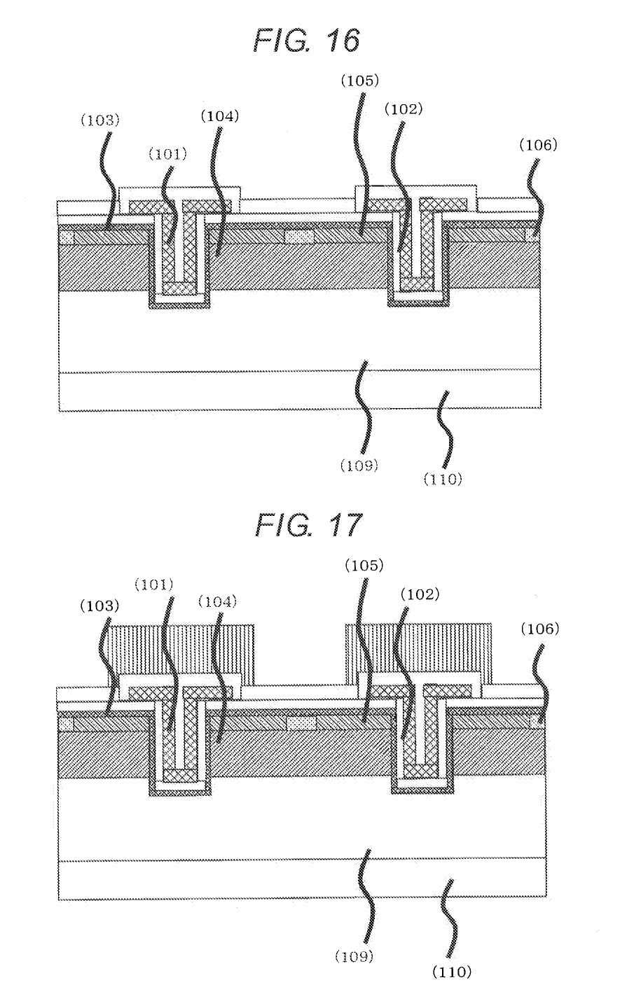

Then, an interlayer insulating film that isolates the gate electrode from the source electrode is formed. Specifically, as illustrated in FIG. 16, SiO₂ is formed through a variety of CVD (chemical vapor deposition) techniques.

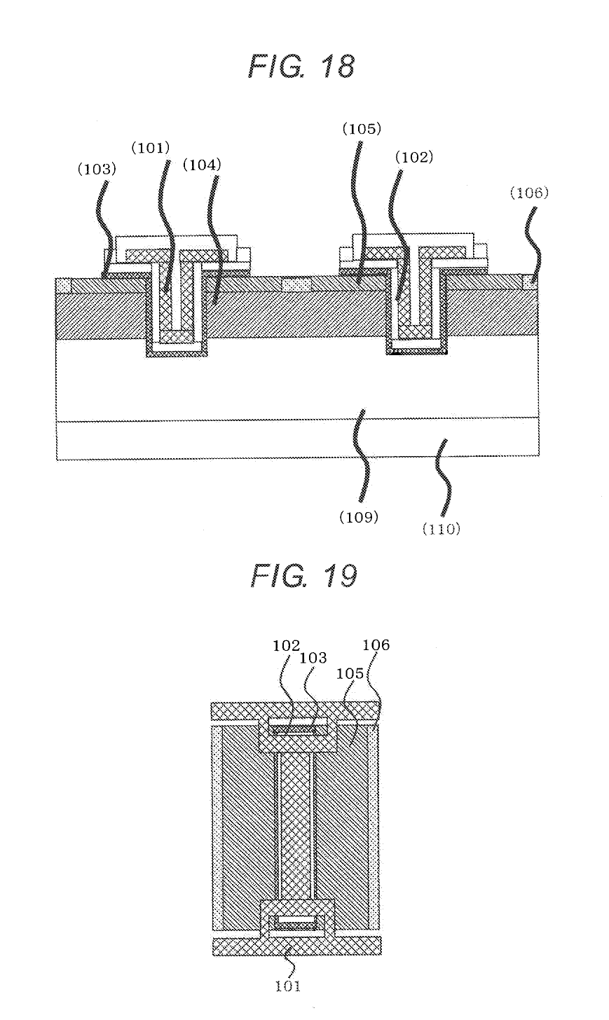

Then, the source electrode is formed. Specifically, as illustrated in FIG. 17, the photoresist film (111) is formed on the interlayer insulating film, a pattern is exposed and transferred, and development processing is conducted. As a result, the photoresist film (111) remains except for a portion where a contact hole is formed. Thereafter, as illustrated in FIG. 18, the contact hole is opened by dry etching or wet etching. Further, the exposed epitaxial film (103) is also removed by dry etching.

Thereafter, a metal material such as nickel (Ni) is deposited on both of the front surface and the rear surface through the sputtering technique, and annealed at about 700 to 1000° C. With this processing, the silicide layer is formed on an opening portion of the contact hole and the rear surface. Thereafter, a metal not subjected to silicide, which remains on the interlayer insulating film, is completely removed by a mixture of sulfuric acid and oxygenated water. Thereafter, as illustrated in FIG. 19, a metal material of a high conductivity such as aluminum is deposited through the sputtering technique to form the source electrode, and a metal material such as nickel is also deposited on the rear surface to form the drain electrode.

With the above processing, the semiconductor device is completed as illustrated in FIG. 2 for now. Thereafter, SiO₂ may be deposited on the surface to form a protective film.

Through the above processing, the semiconductor device (UMOSFET) according to this embodiment is completed.

### Second Embodiment

In the first embodiment, the center portion of the cell region (FIG. 1) has been described, and this region is located within the cell. In this embodiment, an example of a layout of the respective patterns at an, end of the cell region will be described.

### Applied Example 1

FIG. 19 is a plan view of a single cell of a semiconductor device according to an applied example 1 of this embodiment. Referring to FIG. 19, the respective patterns are arranged in the same manner as that of the respective patterns illustrated in FIG. 1. At the cell end, the gate electrode is arranged to avoid the {11-20} surface. With this configuration, an electric field caused by the gate electrode is prevented from being applied to the {11-20} surface on which an even epitaxial film cannot be formed, thereby being capable of improving the yield.

### Third Embodiment

### IGBT

In the first embodiment, the UMOSFET has been specifically described. The same effects are obtained even in a gate trench type IGBT (insulated gate bipolar transistor).

### [Description of Structure]

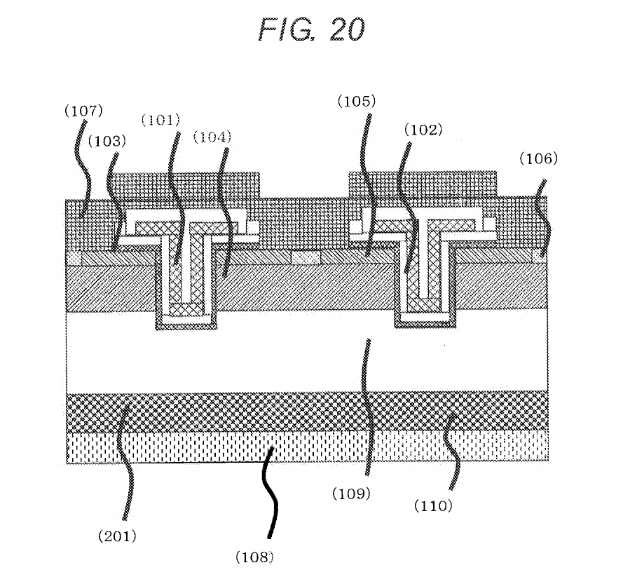

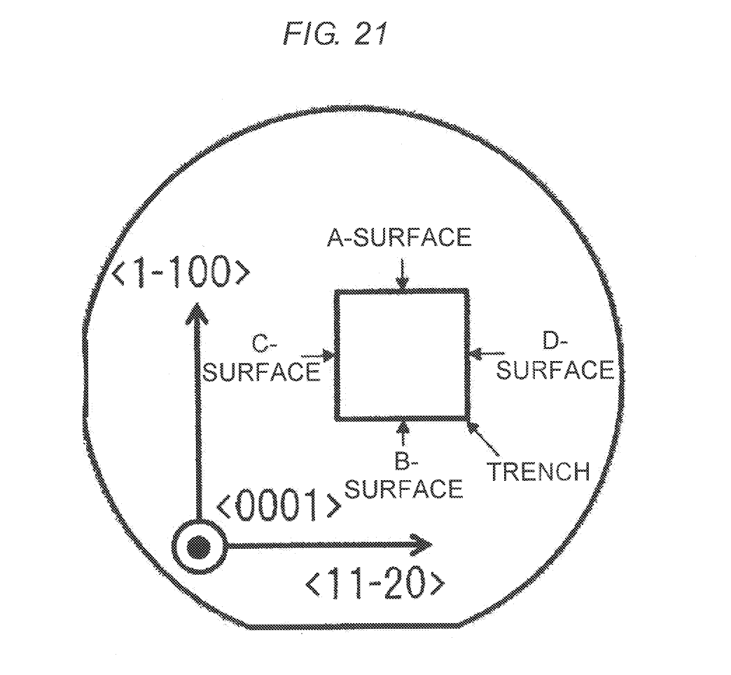

The semiconductor device described below is formed on the substrate in which the SiC epitaxially grown film (109) called “drift layer” is deposited on the SiC substrate (110). The gate electrode (101) illustrated in FIG. 20 is arranged in the center of one cell region. The gate electrode (101) illustrated in FIG. 20 is made of a high melting point metal material such as polycrystal silicon added with impurities or tungsten. The choice of the material is a design particular such as a manufacturing process and a work function of the respective materials. The gate insulating film (102) illustrated in FIG. 20 may be made of a thermally oxidized film such as SiO₂, a deposited film, or a high-permittivity dielectric material such as alumina, and may be formed of a lamination of those films, or a single layer. In the figure, the gate insulating film (102) is illustrated as one lump. The SiC epitaxial growth film (103), the p body region (104), the n+ region (105), and the p+ region (106) are formed as illustrated in the figure. The impurity concentration of those regions is adjusted according to the design of a source resistance, a silicide resistance of a silicide layer formed on the source resistance, a potential maintaining performance and a threshold voltage of the p body region, or an adhesion performance of the p body region and the source electrode (107) formed on the p body region. The source electrode (107) is formed as illustrated in the figure, and made of metal material such as aluminum, and desirably low in resistance. It is desirable that the adhesion of the source electrode (107) and the silicide layer formed below the source electrode (107) is also high. Although not illustrated in the figure, a silicide layer in which a metal material such as Ni chemically reacts with SiC is disposed in an interface between the source electrode and the wafer, and an electric contact of the source electrode (107) and the wafer is formed as an ohmic contact. Similarly, a silicide layer for forming the electric contact as the ohmic contact is formed on a lower portion of the wafer, and a metal material such as Ni or Ti is connected onto the silicide layer to form the drain electrode (108).

A large difference form the first embodiment resides in that the impurity type of the substrate that grows the drift layer is opposite to the drift layer. In the case of the n channel type, the impurity type of the substrate is p-type, and in the p channel type, the impurity type of the substrate is n-type. The semiconductor device is generally called “trench gate type IGBT”, and the voltage to be applied to the gate electrode is so controlled as to control the channel resistance configuring the resistance value between the source electrode (107) and the drain electrode (108). In the case of the IGBT, the source electrode is precisely called “emitter”, and the drain electrode is called “collector”.

### [Description of Manufacturing Method]

The basic manufacturing method is identical with that of the first embodiment. A difference from the first embodiment resides in the substrate forming the device, and the substrate and the drift layer having the same conduction type are formed in the UMOSFET. However, in the IGBT, the conduction type of the substrate is opposite to the conduction type of the drift layer.

What is claimed is:

1. A semiconductor device, comprising:
a trench having two surfaces parallel to an off angle direction, and two or more other surfaces on a first surface side of a substrate; and
an epitaxial growth layer on a trench inner wall.

2. The semiconductor device according to claim 1,
wherein an area per one of the two surfaces parallel to the off angle direction of the trench is larger than any area of the other surfaces.

3. A semiconductor device, comprising:
a channel region including two surfaces parallel to an off angle direction of a trench;
a first source region of a first conduction type which is arranged above a first surface side of a substrate;
a first semiconductor region of a second conduction type which is arranged below the first source region, and has a channel region;
a second semiconductor region of the first conduction type which contacts with the first semiconductor region;
a gate electrode arranged above the channel region through a gate insulating film; and
a buried semiconductor region of the second conduction type which is arranged in the first semiconductor region.

4. The semiconductor device according to claim 3,
wherein the first source region is connected to a first line.

5. The semiconductor device according to claim 3,
wherein the second semiconductor region is connected with a drain electrode arranged on a second surface side of the substrate.

6. The semiconductor device according to claim 3,
wherein the gate electrode is out of contact with the gate insulating film in surfaces other than the two surfaces parallel to the off angle direction of the trench.

7. A semiconductor device, comprising:
a channel region including two surfaces parallel to an off angle direction of a trench;
a first source region of a first conduction type which is arranged above a first surface side of a substrate;
a first semiconductor region of a second conduction type which is arranged below the first source region, and has a channel region;
a second semiconductor region of the second conduction type which contacts with the first semiconductor region;
a gate electrode arranged above the channel region through a gate insulating film; and
a buried semiconductor region of the second conduction type which is arranged in the first semiconductor region.

8. The semiconductor device according to claim 7,
wherein the first source region is connected to a first line.

9. The semiconductor device according to claim 7,
wherein the second semiconductor region is connected with a drain electrode arranged on a second surface side of the substrate.

10. The semiconductor device according to claim 7,
wherein the gate electrode is out of contact with the gate insulating film in surfaces other than the two surfaces parallel to the off angle direction of the trench.
